(19) United States
(12) Patent Application Publication
(10) Pub. No.: US 2026/0286499 A1
(43) Pub. Date: Sep. 24, 2026

(54) DEPOSITION MASK, METHOD OF MANUFACTURING THE SAME, AND ELECTRONIC DEVICE MANUFACTURED USING THE SAME

(71) Applicant: Samsung Display Co., Ltd., Yongin-si (KR)

(72) Inventor: SUNGWOON KIM, Yongin-si (KR)

(21) Appl. No.: 19/566,006

(22) Filed: Mar. 13, 2026

(30) Foreign Application Priority Data
Mar. 19, 2025 (KR) 10-2025-0035561

(51) Int. Cl. C23C 14/04; H10K 59/12

(52) U.S. Cl. CPC C23C 14/042; H10K 59/12

(57) ABSTRACT

A deposition mask is disclosed. The deposition mask may include a base layer having a first opening and a second opening with different widths from each other, and a mask pattern layer arranged on the base layer and including a cell pattern portion overlapping the first opening and a key pattern portion overlapping the second opening, wherein a first virtual line which is substantially parallel to the base layer and passes through a center of the cell pattern portion is substantially parallel to a second virtual line which is substantially parallel to the base layer and passes through a center of the key pattern portion.

### CROSS-REFERENCE TO RELATED APPLICATION

The present application claims priority to and the benefit of Korean Patent Application No. 10-2025-0035561, filed on Mar. 19, 2025, in the Korean Intellectual Property Office, the entire disclosure of which is incorporated herein by reference.

### BACKGROUND

### 1. Field

One or more embodiments of the present disclosure relate to a deposition mask, a method of manufacturing the deposition mask, and an electronic device manufactured utilizing the deposition mask.

### 2. Description of the Related Art

Electronic devices including display panels include a plurality of pixels. Each pixel may include a drive element, such as a thin-film transistor, and a display element, such as an organic light-emitting diode. The display element may be formed by stacking electrodes along with a plurality of organic layers and a plurality of inorganic layers on a substrate.

The electrodes and the organic layers and the inorganic layers in the display element may be a deposition pattern formed in a certain area through a deposition process. Such deposition patterns may be formed utilizing a mask which has openings defined in the certain area (e.g., the desired pattern area).

As display panels utilizing organic light-emitting diodes continue to evolve toward higher resolutions, the mask patterns utilized in their fabrication should also be produced at micrometer-scale dimensions. Accordingly, one or more technologies (studies) are being developed to enable the manufacture of masks with ultra-fine patterns.

### SUMMARY

One or more aspects of embodiments of the present disclosure are directed toward a deposition mask capable of enhancing deposition precision for a deposition process and a method of manufacturing the deposition mask.

One or more aspects of embodiments of the present disclosure are directed toward an electronic device with improved or enhanced display quality by virtue of enhanced deposition precision.

Additional aspects of embodiments will be set forth in part in the description which follows and, in part, will be apparent from the description or may be learned by practice of the presented embodiments of the disclosure.

However, embodiments of the present disclosure are not limited to those set forth herein. The above and other aspects and features of certain embodiments of the present disclosure will become more apparent to one of ordinary skill in the art to which the present disclosure pertains by referencing the detailed description of the present disclosure given.

According to one or more embodiments, a deposition mask includes a base layer having a first opening and a second opening with different widths from each other, and a mask pattern layer arranged on the base layer and including a cell pattern portion overlapping the first opening and a key pattern portion overlapping the second opening, wherein a first virtual line which is substantially parallel to the base layer and passes through a center of the cell pattern portion is substantially parallel to a second virtual line which is substantially parallel to the base layer and passes through a center of the key pattern portion.

In one or more embodiments, the second virtual line may be more adjacent (e.g., closer) to the base layer than the first virtual line may be to the base layer.

In one or more embodiments, the mask pattern layer may include silicon nitride.

In one or more embodiments, a thickness of the mask pattern layer may be in a range of about 0.5 μm to about 2 μm.

In one or more embodiments, the key pattern portion may be spaced farther (or farther apart) from a center of the mask pattern layer than the cell pattern portion may be spaced from the center of the mask pattern layer.

In one or more embodiments, the first opening and the second opening may each be formed or arranged such that a width on one side is smaller than a width on another side.

According to one or more embodiments, a method of manufacturing a deposition mask includes forming a first material layer on a base layer, forming at least one groove in a surface of the first material layer, forming a mask pattern layer on the first material layer, patterning a surface of the mask pattern layer to form a key pattern portion overlapping the at least one groove and a cell pattern portion spaced and/or apart (e.g., spaced apart or separated) from the key pattern portion, forming, in the base layer, a first opening overlapping the cell pattern portion and a second opening overlapping the key pattern portion, and removing the first material layer arranged between the cell pattern portion and the first opening and between the key pattern portion and the second opening.

In one or more embodiments, a width of the at least one groove may be greater than a width of the key pattern portion.

In one or more embodiments, the width of the at least one groove may be equal to or less than twice the width of the key pattern portion.

In one or more embodiments, a thickness of the at least one groove may have a value in a range of about 30% to about 80% of a thickness of the first material layer.

In one or more embodiments, a first virtual line which is substantially parallel to the base layer and passes through a center of the cell pattern portion may be substantially parallel to a second virtual line which is substantially parallel to the base layer and passes through a center of the key pattern portion.

In one or more embodiments, the second virtual line may be more adjacent (e.g., closer) to the base layer than the first virtual line may be to the base layer.

In one or more embodiments, the mask pattern layer may include silicon nitride.

In one or more embodiments, a thickness of the mask pattern layer may be in a range of about 0.5 μm to about 2 μm.

In one or more embodiments, the key pattern portion may be spaced farther (or farther apart) from a center of the mask pattern layer than the cell pattern portion may be spaced from the center of the mask pattern layer.

In one or more embodiments, the first opening and the second opening may each be formed or arranged such that an upper width is smaller than a lower width.

In one or more embodiments, the first material layer may include silicon oxide.

In one or more embodiments, a thickness of the cell pattern portion may be substantially equal to a thickness of the key pattern portion.

In one or more embodiments, a width of the key pattern portion may be smaller than a width of the cell pattern portion.

According to one or more embodiments, an electronic device includes a substrate, a plurality of thin-film transistors arranged on the substrate, a plurality of pixel electrodes electrically connected to the plurality of thin-film transistors, a plurality of intermediate layers arranged on the plurality of pixel electrodes, and a counter electrode arranged on the plurality of intermediate layers, wherein at least one selected from among the plurality of thin-film transistors, the plurality of pixel electrodes, the plurality of intermediate layers, and the counter electrodes is formed or applied utilizing the deposition mask as described in one or more embodiments.

For example, the deposition mask and associated manufacturing method described herein enable precise patterning of functional layers in electronic devices, for example, display panels. By enhancing the geometry and alignment of mask features, such as cell and key pattern portions, the disclosed technology supports high-resolution deposition processes. This contributes to improved or enhanced device performance and reliability, e.g., in applications requiring fine pixel structures and uniform (e.g., substantially uniform) material deposition.

Other aspects, effects, and/or embodiments of the present disclosure will become better understood through the detailed description, the appended claims and equivalents thereof, and the accompanying drawings.

### BRIEF DESCRIPTION OF THE DRAWINGS

The above and other aspects and features of certain embodiments of the present disclosure will be more apparent from the following description taken in conjunction with the accompanying drawings in which:

FIG. 1 is a schematic cross-sectional view of an apparatus of manufacturing a display device according to one or more embodiments;

FIG. 2 is a schematic plan view of a deposition mask according to one or more embodiments;

FIG. 3 is a schematic cross-sectional view of the deposition mask taken along the line I-I′ of FIG. 2;

FIG. 4 is an enlarged view of the area AA of FIG. 3;

FIG. 5 is an enlarged view of the area BB of FIG. 3;

FIGS. 6-11 are schematic cross-sectional views of a method of manufacturing a deposition mask according to one or more embodiments;

FIG. 12 is a schematic perspective view of a display device according to one or more embodiments;

FIG. 13 is a schematic cross-sectional view of a display device according to one or more embodiments;

FIG. 14 is a view of an equivalent circuit of a pixel in a display device according to one or more embodiments;

FIG. 15 is a schematic cross-sectional view of a display panel according to one or more embodiments;

FIG. 16 is a block diagram of an electronic device according to one or more embodiments; and

FIG. 17 is a set of schematic views of electronic devices according to one or more embodiments.

### DETAILED DESCRIPTION

The subject matter of the present disclosure will be described more fully hereinafter with reference to the accompanying drawings, in which one or more suitable embodiments of the present disclosure are shown. The subject matter of the present disclosure may, however, be embodied in different forms and should not be construed as being limited to the embodiments set forth herein, and one or more changes and modifications can be made. Rather, these embodiments are provided so that this disclosure will be thorough and complete and will fully convey the aspects and features of the present disclosure to those skilled in the art to which the present disclosure pertains.

The utilization of “may,” if (e.g., when) describing embodiments of the present disclosure, refers to “one or more embodiments of the present disclosure.”

In the context of the present application and unless otherwise defined, the terms “use,” “using,” and “used” may be considered synonymous with the terms “utilize,” “utilizing,” and “utilized,” respectively.

In the present disclosure, the terms “first,” “second,” and/or the like are not used in a restrictive sense and are used to distinguish one element from another element. For instance, a first element discussed herein may be termed a second element without departing from the scope of the present disclosure. Similarly, the second element may also be termed the first element.

The singular forms as used herein are intended to include the plural forms as well unless the context clearly indicates otherwise. As used herein, “a,” “an,” “the,” and “at least one” do not denote a limitation of quantity and are intended to include both (e.g., simultaneously) the singular and plural, unless the context clearly indicates otherwise. For example, “an element” has substantially the same meaning as “at least one element,” unless the context clearly indicates otherwise. “At least one” is not to be construed as limiting “a” or “an.”

“Or” refers to “and/or.” As used herein, the term “and/or” includes any and all combinations of one or more of the associated listed items.

It will be further understood that the terms “has,” “includes,” “having,” and/or “including” used herein specify the presence of stated features or elements, but do not preclude the presence or addition of one or more other features or elements. For example, it should be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Also, the terms “comprise(s)/comprising,” “include(s)/including,” “have/has/having,” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

“About” or “approximately” as used herein is inclusive of the stated value and refers to being within an acceptable range of deviation for the particular value as determined by one of ordinary skill in the art, considering the measurement in question and the error associated with measurement of the particular quantity (e.g., the limitations of the measurement system). For example, “about” may refer to being within one or more standard deviations, or within ±30%, ±20%, ±10%, or ±5% of the stated value.

Also, it should be understood that, even if (e.g., when) the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

In the present disclosure, it will be understood that, if (e.g., when) a portion, such as a film, a region, or an element, is referred to as being “on” another portion, this may include not only a case where the portion is directly on the other portion, but also a case where intervening films, regions, or elements may be present therebetween. In contrast, if (e.g., when) a portion is referred to as being “directly on” another portion, there may be no intervening films, regions, or elements present therebetween.

Sizes of elements in the drawings may be exaggerated or reduced for convenience of explanation. For example, because sizes and/or thicknesses of elements in the drawings are arbitrarily illustrated for convenience of explanation, embodiments of the present disclosure are not limited thereto.

In the following examples, an x-axis, a y-axis, and a z-axis are not limited to three axes on an orthogonal coordinate system, and may be interpreted in a broad sense that includes such axes. For example, the x-axis, the y-axis, and the z-axis may be orthogonal to one another, but may also represent different directions that are not orthogonal to one another.

In the context of the present disclosure and unless otherwise defined, plan view is an orthographic projection of a three-dimensional object from the position of a horizontal plane that intersects the object. For example, it is a top-down view, showing the layout and spatial relationships of one or more elements within the object or structure. A plan view based on a z-axis (thickness) direction refers to a top-down view of the object, as if (e.g., when) looking directly down onto the surface from above. In this context, the z-axis direction is perpendicular or normal to the horizontal plane defined by x-axis and y-axis directions.

A specific process order may be performed differently from the described order if (e.g., when) a certain embodiment may be implemented differently. For example, two processes described in succession may be performed substantially at the same time or may be performed in a reverse order opposite to that described.

Hereinafter, one or more embodiments of the present disclosure will be described in more detail with reference to the accompanying drawings. In describing one or more embodiments with reference to the accompanying drawings, substantially the same or corresponding elements are denoted by the same reference numeral, and redundant descriptions thereof may not be provided.

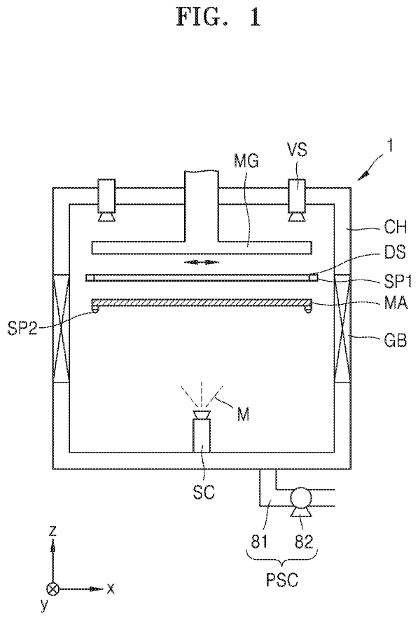

FIG. 1 is a schematic cross-sectional view of an apparatus of manufacturing a display device according to one or more embodiments.

A manufacturing apparatus 1 of a display device may include a chamber CH, a first support part SP1, a second support part SP2, a deposition mask MA, a deposition source SC, a magnetic force part MG, a vision part VS, and a pressure adjustment part PSC.

The chamber CH may have a space inside, and a display substrate DS and the deposition mask MA may be received in the chamber CH. At this time, a portion of the chamber CH may be formed or arranged to be open, and a gate valve GB may be installed in the open portion of the chamber CH. The open portion of the chamber CH may be open or closed according to the operation of the gate valve GB.

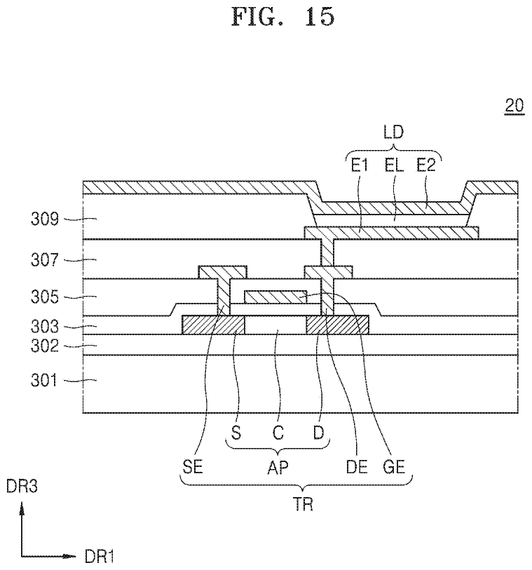

At this time, the display substrate DS may refer to a display substrate DS in the process of manufacturing a display device, on which at least one of an organic layer, an inorganic layer, or a metal layer is deposited on a substrate 301 (see FIG. 15) to be described herein in more detail. In one or more embodiments, the display substrate DS may be a substrate on which none of the organic layer, inorganic layer, and metal layer has been deposited yet.

The first support part SP1 may be to support the display substrate DS. At this time, the first support part SP1 may include a plate fixed inside the chamber CH. In one or more embodiments, the first support part SP1 may include a shuttle on which the display substrate DS is placed and which is linearly movable inside the chamber CH. In one or more embodiments, the first support part SP1 may include an electrostatic chuck or an adhesive chuck which is fixed to the chamber CH or positioned in the chamber CH to be movable inside the chamber CH.

The second support part SP2 may be to support the deposition mask MA. At this time, the second support part SP2 may be arranged inside the chamber CH. The second support part SP2 may be to finely adjust the position of the deposition mask MA. The second support part SP2 may include a separate driver or alignment unit to enable the deposition mask MA to move in different directions.

In one or more embodiments, the second support part SP2 may include a shuttle. In this case, the deposition mask MA may be placed on the second support part SP2, and the second support part SP2 may be to transfer the deposition mask MA. For example, the second support part SP2 may be to move to the outside of the chamber CH such that the deposition mask MA is placed thereon, and then move from the outside to the inside of the chamber CH.

In this case, the first support part SP1 and the second support part SP2 may also be formed integrally with each other. In this example, the first support part SP1 and the second support part SP2 may include a movable shuttle. At this time, the first support part SP1 and the second support part SP2 may include a structure which fixes the deposition mask MA and the display substrate DS in a state where the display substrate DS is placed on the deposition mask MA, and it may also be desirable to linearly move the display substrate DS and the deposition mask MA concurrently (e.g., simultaneously).

However, for the convenience of explanation, the following description will be given in more detail of an example in which the first support part SP1 and the second support part SP2 are formed separate from each other and arranged on different positions, and an example in which the first support part SP1 and the second support part SP2 are arranged inside the chamber CH.

The deposition mask MA may be arranged to oppose the display substrate DS inside the chamber CH. A deposition material M may be deposited on the display substrate DS through the deposition mask MA.

The deposition source SC may be arranged to oppose the deposition mask MA and may be to supply the deposition material M so that (e.g., such that) the deposition material M is deposited on the display substrate DS through the deposition mask MA. At this time, the deposition source SC may be to evaporate or sublimate the deposition material M by applying heat to the deposition material M. The deposition source SC may be positioned fixedly inside the chamber CH or may be positioned inside the chamber CH to be movable linearly along one direction.

The magnetic force part MG may be arranged inside the chamber CH to oppose the display substrate DS and/or the deposition mask MA. At this time, the magnetic force part MG may be to apply a magnetic force to the deposition mask MA such that the deposition mask MA is pushed toward the display substrate DS.

The vision part VS may be arranged in the chamber CH and may be to capture the positions of the display substrate DS and deposition mask MA. At this time, the vision part VS may include a camera which captures the display substrate DS and the deposition mask MA. Based on images captured in the vision part VS, the positions of the display substrate DS and the deposition mask MA may be identified, and any deformation of the deposition mask MA may be confirmed. On the basis of the images, the position of the display substrate DS on the first support part SP1 may be finely adjusted or the position of the deposition mask MA on the second support part SP2 may be finely adjusted. However, the following description will be given in more detail of an example in which the positions of the display substrate DS and the deposition mask MA are aligned by finely adjusting the position of the deposition mask MA on the second support part SP2.

The pressure adjustment part PSC may be connected to the chamber CH to adjust internal pressure of the chamber CH. For example, the pressure adjustment part PSC may be to adjust the internal pressure of the chamber CH to be substantially equal or similar to atmospheric pressure. In one or more embodiments, the pressure adjustment part PSC may be to adjust the internal pressure of the chamber CH to be substantially equal or similar to a vacuum state.

The pressure adjustment part PSC may include a connecting pipe 81 connected to the chamber CH and a pump 82 installed in the connecting pipe 81. As the pump 82 is operated, external air may be introduced through the connecting pipe 81 or gas inside the chamber CH may be guided to the outside through the connecting pipe 81.

In one or more embodiments, describing a method of manufacturing a display device utilizing the manufacturing apparatus 1 of the display device, the display substrate DS may first be prepared.

The pressure adjustment part PSC may be to maintain the inside of the chamber CH substantially at the same or similar pressure as or to atmospheric pressure, and the gate valve GB may be operated to open the open portion of the chamber CH.

Afterwards, the display substrate DS may be loaded from the outside to the inside of the chamber CH. The display substrate DS may be loaded into the chamber CH in one or more suitable ways. For example, the display substrate DS may be loaded into the chamber CH from the outside of the chamber CH by means of a robot arm and/or the like arranged outside the chamber CH. In one or more embodiments, if (e.g., when) the first support part SP1 has a shuttle shape, the first support part SP1 which is inside the chamber CH may be drawn out of the chamber CH, the display substrate DS may be placed on the first support part SP1 utilizing a separate robot arm and/or the like arranged outside the chamber CH, and the first support part SP1 may be loaded from the outside to the inside of the chamber CH.

The deposition mask MA may be in a state of being placed inside the chamber CH as described in one or more embodiments. In one or more embodiments, the deposition mask MA may be loaded into the chamber CH from the outside of the chamber CH in substantially the same or similar manner as or to the display substrate DS.

If (e.g., when) the display substrate DS is loaded into the chamber CH, the display substrate DS may be placed on the first support part SP1. At this time, the vision part VS may be to capture the positions of the display substrate DS and the deposition mask MA. The positions of the display substrate DS and the deposition mask MA may be identified based on images captured in the vision part VS. At this time, the manufacturing apparatus 1 of the display device may include a separate control unit which identifies the positions of the display substrate DS and the deposition mask MA.

Once the positions of the display substrate DS and the deposition mask MA are identified, the second support part SP2 may finely adjust the position of the deposition mask MA.

Afterwards, the deposition source SC may be operated to supply the deposition material M toward the deposition mask MA, and the deposition material M passing through the deposition mask MA may be deposited on the display substrate DS. The deposition source SC may be to move substantially parallel to the display substrate DS and the deposition mask MA, or the display substrate DS and the deposition mask MA may be to move substantially parallel to the deposition source SC. For example, the deposition source SC may be to move relative to the display substrate DS and the deposition mask MA. At this time, the pump 82 may be to intake gas inside the chamber CH and discharge the gas to the outside of the chamber CH, thereby maintaining the internal pressure of the chamber CH in a state which is substantially equal or similar to a vacuum state.

As described in one or more embodiments, the deposition material M supplied from the deposition source SC may be deposited on the display substrate DS through the deposition mask MA, thereby forming at least one selected from among a plurality of layers, for example, an organic layer, an inorganic layer, and a metal layer, which are stacked on the display device to be described herein in more detail.

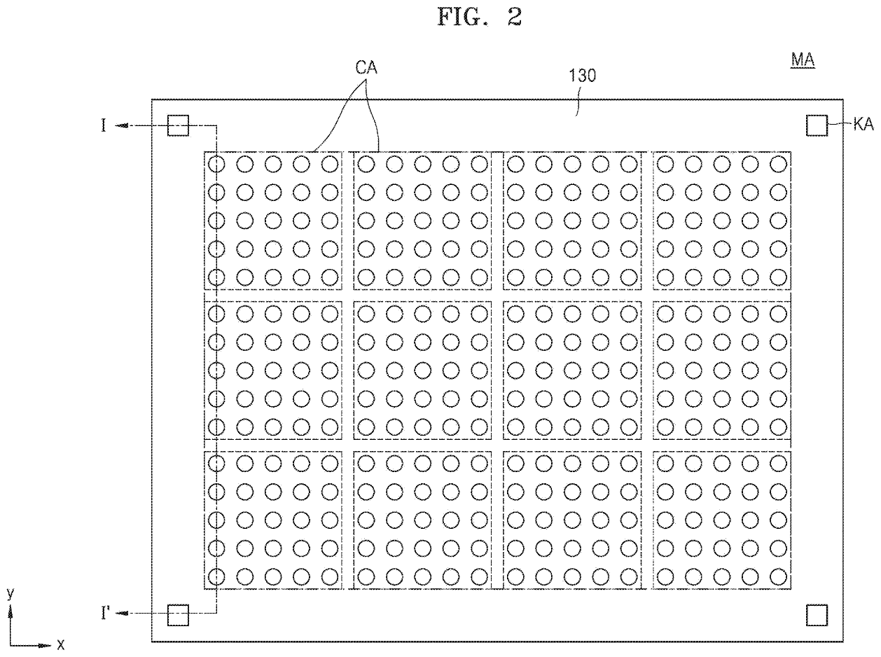

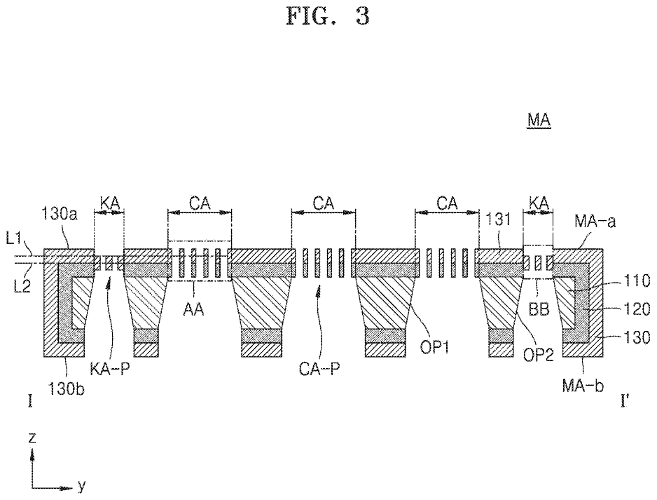

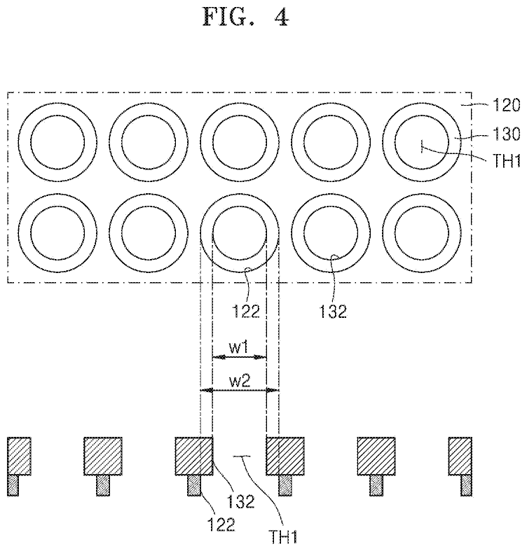

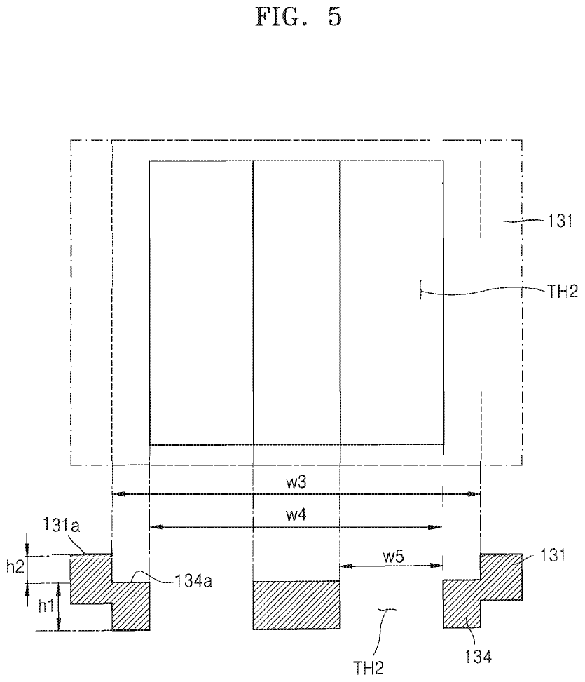

FIG. 2 is a schematic plan view of a deposition mask according to one or more embodiments, and FIG. 3 is a schematic cross-sectional view of the deposition mask taken along the line I-I′ of FIG. 2. FIG. 4 is an enlarged view of the area AA of FIG. 3, and FIG. 5 is an enlarged view of the area BB of FIG. 3.

A deposition mask MA according to one or more embodiments may be a mask which is utilized to manufacture an ultra-high-resolution display. For example, the deposition mask MA may be a mask which is utilized to manufacture a display in an extended reality (XR) device, such as a virtual reality (VR) device, an augmented reality (AR) device, or a mixed reality (MR) device.

In one or more embodiments, the deposition mask MA may be utilized to perform a pixel deposition process on silicon wafers other than large-scale substrates utilized in the related art displays. For displays in XR devices, a screen may be directly in front of a user's eyes. Therefore, such XR devices may have small screens rather than large screens. The XR devices may also require ultra-high resolutions because such devices are close to the user's eyes. For example, the displays in the XR devices may require or be desired to have resolutions of about at least 1000 pixels per inch (PPI) and may require or be desired to have ultra-high resolutions of at least 2000 PPI. The deposition mask MA according to one or more embodiments may be a mask which is utilized to manufacture such an ultra-high-resolution display.

Referring to FIGS. 2 to 5, the deposition mask MA may include a base layer 110, a first material layer 120, and a mask pattern layer 130. In one or more embodiments, the deposition mask MA may include a cell area CA and a key area KA. Herein, the cell area CA and the key area KA may be areas which are formed by dividing the deposition mask MA by a line normal (e.g., substantially perpendicular) to a surface MA-a of the deposition mask MA and may be defined as an area where a cell pattern portion CA-P is arranged and an area where a key pattern portion KA-P is arranged, respectively.

In one or more embodiments, the cell area CA may be positioned at a central portion of the deposition mask MA in case of being viewed on a plane. Herein, “in case of being viewed on a plane” may be defined as a state in which the surface MA-a of the deposition mask MA on which the cell pattern portion CA-P and the key pattern portion KA-P are formed is viewed in a-z direction. The cell area CA may be arranged as a plurality of cell areas, and the plurality of cell areas CA may form a certain arrangement.

In one or more embodiments, the key area KA may be arranged in an outer portion which is outside the cell area CA. The key area KA of the deposition mask MA may be spaced farther from the center of the deposition mask MA than the cell area CA may be spaced from the center of the deposition mask MA.

The key area KA may be arranged as a plurality of key areas. For example, if (e.g., when) the deposition mask MA has a square flat plate shape (e.g., a substantially square flat plate shape; e.g., in a form of plates), the key areas KA may be arranged at respective corners of the deposition mask MA. However, embodiments of the present disclosure are not limited thereto, and, in one or more embodiments, the key area KA may be positioned between the cell areas CA which are adjacent (e.g., close) to each other.

In one or more embodiments, the base layer 110 may include a silicon substrate. Silicon substrates may be processed by fine and precise processes, compared to large-scale substrates, by utilizing technologies developed in semiconductor processes, thus, to be utilized as substrates of ultra-high-resolution displays. In one or more embodiments, the deposition mask MA may substantially equally utilize the silicon mask to form pixels on the silicon substrate of the ultra-high resolution display.

The shape of the base layer 110 may correspond to the shape of the display substrate DS (see FIG. 1). For example, the base layer 110 may have substantially the same size or shape as the display substrate DS. However, embodiments of the present disclosure are not limited thereto, and, in one or more embodiments, the base layer 110 may have a larger size than the display substrate DS. For example, the base layer 110 may include a material, such as glass, quartz, and/or a polymer resin.

The base layer 110 may include a first opening OP1 and a second opening OP2 which are formed or arranged through the base layer 110 in a thickness direction (e.g., a z direction). The first opening OP1 may overlap the cell area CA, and the second opening OP2 may overlap the key area KA.

The first opening OP1 or the second opening OP2 may be formed or arranged so that (e.g., such that) a width of a side adjacent (e.g., close) to the cell pattern portion CA-P or the key pattern portion KA-P is smaller than a width of another side opposite to the side. In one or more embodiments, the first opening OP1 or the second opening OP2 may be formed or arranged such that an inner circumferential surface is inclined with respect to the surface MA-a of the deposition mask MA. However, embodiments of the present disclosure are not limited thereto, and the first opening OP1 or the second opening OP2 may be formed or arranged such that the inner circumferential surface is normal (e.g., substantially perpendicular) to the surface MA-a of the deposition mask MA.

The first opening OP1 and the second opening OP2 may have different cross-sectional sizes in a direction normal (e.g., substantially perpendicular) to the thickness direction (the z direction) of the base layer 110. In one or more embodiments, the width of the first opening OP1 may be greater than the width of the second opening OP2. Herein, the width of the first opening OP1 or the second opening OP2 may refer to a width on a cross-section of the base layer 110 which is cut normal (e.g., substantially perpendicularly) to the thickness direction (the z direction).

The first opening OP1 and the second opening OP2 may be to provide passages through which the deposition material M (see FIG. 1) passes. A portion of the base layer 110 where the first opening OP1 or the second opening OP2 is not formed may be to shield the deposition material not to pass through the portion and may serve to support the mask pattern layer 130.

The first material layer 120 may be arranged on the base layer 110. The first material layer 120 may be between the base layer 110 and the mask pattern layer 130. In one or more embodiments, the first material layer 120 may fully (e.g., substantially fully) cover an outer surface of the base layer 110. The first material layer 120 may be formed as an insulating (e.g., electrically insulating) layer which includes a material, such as silicon oxide.

The mask pattern layer 130 may be arranged on the first material layer 120. In one or more embodiments, the mask pattern layer 130 may fully (e.g., substantially fully) cover an outer surface of the first material layer 120. For example, the mask pattern layer 130 may form the surface MA-a and another surface MA-b of the deposition mask MA. In an example, a surface 130a of the mask pattern layer 130 may form the surface MA-a of the deposition mask MA, and another surface 130b of the mask pattern layer 130 may form the other surface MA-b of the deposition mask MA.

The mask pattern layer 130 may include a material which may be patterned by a semiconductor process. For example, the mask pattern layer 130 may be formed as an insulating (e.g., electrically insulating or insulator) layer which includes a material, such as silicon nitride. For example, the mask pattern layer 130 may have a thickness in the range of about 0.5 μm to about 2 μm, for example, about 1 μm to about 2 μm.

The cell pattern portion CA-P and the key pattern portion KA-P may be on the surface 130a of the mask pattern layer 130. A first virtual line L1 which passes through the center of the cell pattern portion CA-P in the thickness direction (e.g., the z direction) of the cell pattern portion CA-P may be substantially parallel to a second virtual line L2 which passes through the center of key pattern portion KA-P in the thickness direction (e.g., the z direction) of the key pattern portion KA-P. Herein, both (e.g., simultaneously) the first virtual line L1 and the second virtual line L2 may be lines substantially parallel to the base layer 110 and may extend substantially parallel to each other without overlapping or crossing each other.

The second virtual line L2 may be arranged more adjacent (e.g., closer) to the base layer 110 than the first virtual line L1 may be to the base layer 110. For example, the center of the key pattern portion KA-P in the thickness direction (e.g., the z direction) may be positioned more adjacent (e.g., closer) to the base layer 110 than the center of the cell pattern portion CA-P may be to the base layer 110 in the thickness direction (e.g., the z direction).

The cell pattern portion CA-P may include a plurality of first through holes TH1. The plurality of first through holes TH1 may form a certain (e.g., set or predetermined) arrangement. For example, the plurality of first through holes TH1 may be arranged in a grid shape (e.g., a substantially grid shape).

FIGS. 2 and 4 are examples in which the shape of the first through hole TH1 in plan view is circular (e.g., substantially circular), but embodiments of the present disclosure are not limited thereto, and the shape of the first through hole TH1 may change to one or more suitable shapes, such as an oval (e.g., substantially an oval) or a polygon (e.g., substantially a polygon), depending on the purpose and use.

The first through hole TH1 may be formed in the cell area CA through the mask pattern layer 130 and/or the first material layer 120 in the thickness direction (e.g., the z direction). The first through hole TH1 may be to provide a passage through which the deposition material M (see FIG. 1) applied from the other surface MA-b of the deposition mask MA passes through the mask pattern layer 130 and/or the first material layer 120.

In one or more embodiments, as illustrated in FIG. 4, the cell area CA may have a structure in which the mask pattern layer 130 and the first material layer 120 are stacked. In this case, the first through hole TH1 may be formed through both (e.g., simultaneously) the mask pattern layer 130 and the first material layer 120.

In one or more embodiments, the first through hole TH1 may include a third opening 132 and a fourth opening 122. The third opening 132 may be formed through the mask pattern layer 130, and the fourth opening 122 may be formed through the first material layer 120. The third opening 132 and the fourth opening 122 may overlap each other. On a cross-section of the deposition mask MA cut in the thickness direction (the z direction), a width w1 of the third opening 132 may be smaller than a width w2 of the fourth opening 122. In plan view, an area of the third opening 132 may be smaller than an area of the fourth opening 122.

In one or more embodiments, the first through hole TH1 and the first opening OP1 of the base layer 110 may overlap each other. Therefore, the deposition material M (see FIG. 1) may sequentially pass through the first opening OP1, the fourth opening 122, and the third opening 132. The width of the first opening OP1 may be greater than or equal to a width of the cell pattern portion CA-P in which the plurality of first through holes TH1 are arranged.

The key pattern portion KA-P may include at least one second through hole TH2. The second through hole TH2 may be formed in the key area KA through the mask pattern layer 130 in the thickness direction (e.g., the z direction). The second through hole TH2 may be to perform alignment with the display substrate DS.

FIG. 5 is an example in which the shape of the second through hole TH2 in plan view is rectangular (e.g., substantially rectangular), but embodiments of the present disclosure are not limited thereto, and the shape of the second through hole TH2 may change to one or more suitable shapes, such as a square or a cross, depending on the purpose and use.

As illustrated in FIG. 5, the key pattern portion KA-P in the key area KA may include only the mask pattern layer 130. For example, only the mask pattern layer 130 may be arranged in the key area KA, and both (e.g., simultaneously) the base layer 110 and the first material layer 120 may be removed. As the base layer 110 and the first material layer 120 are removed from the key area KA, the alignment of the deposition mask MA and the display substrate DS (see FIG. 1) utilizing the key pattern portion KA-P may be performed more quickly and precisely.

A width w3 of the key area KA may be greater than a width w5 of the second through hole TH2. In one or more embodiments, if (e.g., when) the key area KA includes a plurality of second through holes TH2, the width w3 of the key area KA may be greater than a width w4 of the key pattern portion KA-P. At this time, the key pattern portion KA-P may be defined along an outermost periphery of the second through holes TH2. A size of the key area KA on a plane may be greater than a size of the key pattern portion KA-P. For example, the size of the key area KA may have a value in the range of about 1 to 2 times the size of the key pattern portion KA-P. In one or more embodiments, the width w5 of the second through hole TH2 may be greater than the width w1 of the first through hole TH1.

The mask pattern layer 130 may include a first portion 131 corresponding to an area except for the key area KA and a second portion 134 arranged in the key area KA. The second through hole TH2 may be formed in the second portion 134. The first portion 131 and the second portion 134 may be formed integrally with each other. The first portion 131 and the second portion 134 may have substantially the same thickness, but embodiments of the present disclosure are not limited thereto.

One surface 131a of the first portion 131 and one surface 134a of the second portion 134 may form a step. In one or more embodiments, the surface 134a of the second portion 134 may be made lower than the surface 131a of the first portion 131 by a second height h2 in a direction (e.g., a-z direction) in which the base layer 110 is arranged. For example, the second height h2 by which the second portion 134 is lowered may have a value in the range of about 30% to about 80%, for example, about 50% to about 80%, of a thickness h1 of the second portion 134.

As the surface 134a of the second portion 134 is inwardly lowered with respect to the surface 131a of the first portion 131, the key pattern portion KA-P may be suppressed or reduced from being damaged due to contact between the deposition mask MA and the display substrate DS if (e.g., when) the deposition mask MA moves toward the display substrate DS.

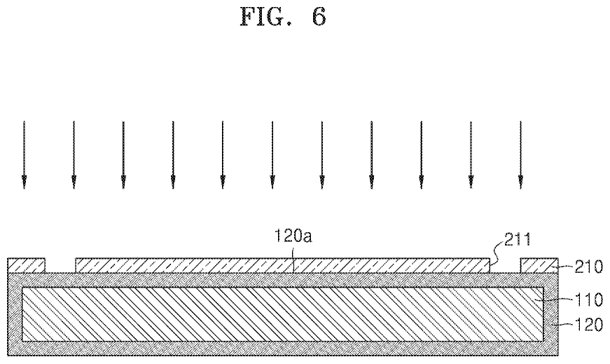

FIGS. 6 to 11 are schematic cross-sectional views of a method of manufacturing a deposition mask according to one or more embodiments.

Hereinafter, a method of manufacturing a deposition mask according to one or more embodiments will be described in more detail with reference to FIGS. 6 to 11. First, as illustrated in FIG. 6, a first material layer 120 may be on a base layer 110. The base layer 110 and the first material layer 120 may include a material which may be patterned by a semiconductor process.

For example, the base layer 110 may be a base substrate which includes silicon material. The base layer 110 may be a silicon wafer. The first material layer 120 may be formed as an insulating (e.g., electrically insulating) layer which includes a material, such as silicon oxide.

The first material layer 120 may be to suppress deformation or damage (or to reduce a degree or occurrence of deformation or damage) of a mask pattern layer 130, which is stacked on the first material layer 120, during a process of manufacturing the deposition mask. In one or more embodiments, the first material layer 120 may be stacked on the base layer 110 together with the mask pattern layer 130, to offset a tensile stress of the mask pattern layer 130.

Next, at least one first groove 120H may be formed in a surface 120a of the first material layer 120. The first groove 120H may be formed or arranged to correspond to the number, position, and size of a key area KA, in which a key pattern portion KA-P to be described herein in more detail is arranged. In one or more embodiments, the size of the first groove 120H on a plane may correspond to a field of view of a vision part VS of a manufacturing apparatus 1 (see FIG. 1) of a display device.

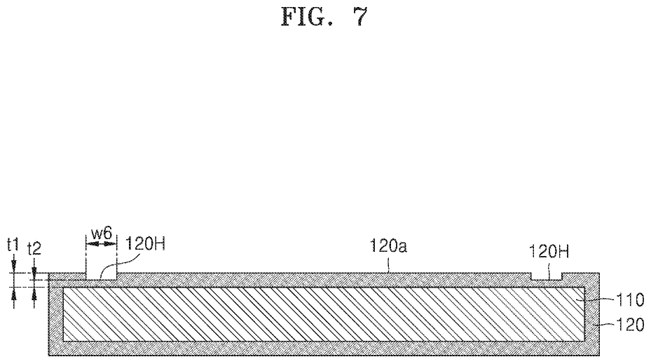

In one or more embodiments, as illustrated in FIG. 6, a first photoresist 210 may be stacked on the first material layer 120 and exposed utilizing a photomask. A development process may then be performed to form a first pattern 211 corresponding to the first groove 120H in the first photoresist 210. Next, as illustrated in FIG. 7, the surface 120a of the first material layer 120 may be patterned utilizing the first pattern 211 of the first photoresist 210 to form the first groove 120H. In one or more embodiments, the first material layer 120 may be patterned through a dry etching process, such as reactive-ion etching (RIE).

As the first groove 120H is on the first material layer 120, a thickness of the first material layer 120 arranged in the key area KA may have a value smaller than a thickness of the first material layer 120 arranged in a cell area CA.

A thickness t2 of the first groove 120H may have a value selected in a range of about 30% to about 80% of a thickness t1 of the first material layer 120 in the key area KA before the first groove 120H is formed, and, for example, may have a value selected in a range of about 50% to about 80% of the thickness t1. A width w6 of the first groove 120H may be substantially equal to a width w3 (see FIG. 5) of the key area KA and may be greater than a width w4 (see FIG. 5) of the key pattern portion KA-P.

If (e.g., when) the first groove 120H is completely (e.g., substantially completely) formed, the first photoresist 210 may be removed from the surface 120a of the first material layer 120, as illustrated in FIG. 7. The removal of the first photoresist 210 may be performed through a dry process or a wet process.

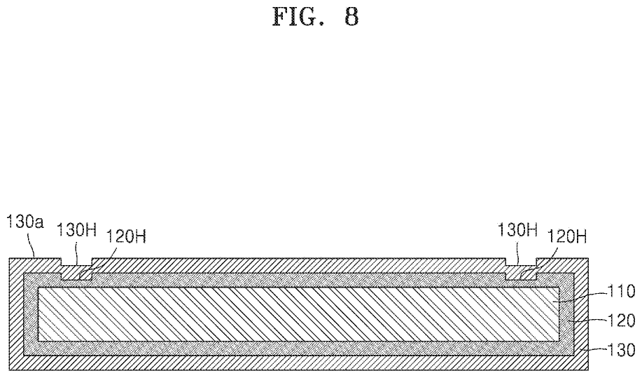

Next, as illustrated in FIG. 8, the mask pattern layer 130 may be on the first material layer 120, on which the first groove 120H is formed. For example, the mask pattern layer 130 may be formed as an insulating (e.g., electrically insulating) layer which includes a material, such as silicon nitride. For example, the mask pattern layer 130 may have a thickness in the range of about 0.5 μm to about 2 μm, for example, about 1 μm to about 2 μm.

A second groove 130H may be in a surface 130a of the mask pattern layer 130 to be lowered inward by the first groove 120H in a direction from the surface 130a of the mask pattern layer 130 toward the base layer 110.

In the accompanying drawings, the first material layer 120 and the mask pattern layer 130 are stacked on opposite surfaces of the base layer 110, but the first material layer 120 and the mask pattern layer 130 may be stacked only on a single surface of the base layer 110.

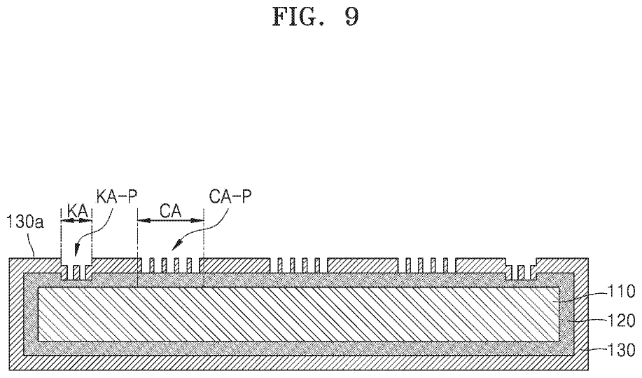

Next, as illustrated in FIG. 9, a cell pattern portion CA-P and a key pattern portion KA-P may be on the surface 130a of the mask pattern layer 130.

The cell pattern portion CA-P may overlap the cell area CA, and the key pattern portion KA-P may overlap the key area KA. In one or more embodiments, the key pattern portion KA-P may be spaced farther (or farther apart) from the center of the mask pattern layer 130 than the cell pattern portion CA-P may be spaced from the center of the mask pattern layer 130.

For example, the cell pattern portion CA-P and the key pattern portion KA-P may be formed through photolithography and dry etching processes, but embodiments of the present disclosure are not limited thereto, and one or more suitable patterning methods, such as laser lithography, may be used.

A first virtual line L1 which passes through the center of the cell pattern portion CA-P may be substantially parallel to a second virtual line L2 which passes through the center of the key pattern portion KA-P. Herein, both (e.g., simultaneously) the first virtual line L1 and the second virtual line L2 may be lines substantially parallel to the base layer 110 and may extend substantially parallel to each other without overlapping or crossing each other.

The second virtual line L2 may be arranged more adjacent (e.g., closer) to the base layer 110 than the first virtual line L1 may be to the base layer 110. For example, the center of the key pattern portion KA-P may be arranged more adjacent (e.g., closer) to the base layer 110 than the center of the cell pattern portion CA-P may be to the base layer 110.

Next, a first opening OP1 and a second opening OP2 may be formed through the base layer 110. The first opening OP1 may be formed or arranged to overlap the cell area CA, and the second opening OP2 may be formed or arranged to overlap the key area KA.

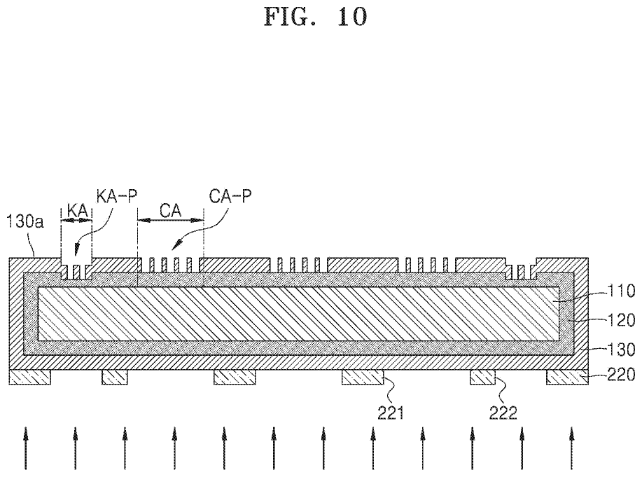

In one or more embodiments, as illustrated in FIG. 10, a second photoresist 220 may be stacked on another surface opposite to the surface 130a of the mask pattern layer 130, and a second pattern 221 corresponding to the first opening OP1 and a third pattern 222 corresponding to the second opening OP2 may be formed through the second photoresist 220 utilizing a photomask. This embodiment illustrates the example in which the first material layer 120 and the mask pattern layer 130 are stacked on the opposite surfaces of the base layer 110, and accordingly the second photoresist 220 may be stacked on the other surface of the mask pattern layer 130.

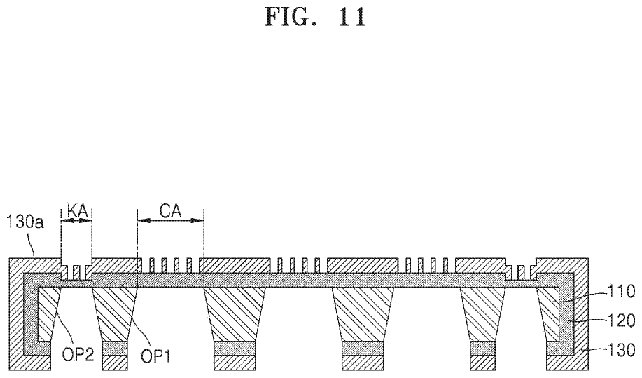

Next, as illustrated in FIG. 11, the base layer 110 may be patterned utilizing the second pattern 221 and the third pattern 222 of the second photoresist 220, thereby forming the first opening OP1 and the second opening OP2. The base layer 110 may be etched through a deep reactive-ion etching (DRIE) process. At this time, the first material layer 120 which is stacked on the cell pattern portion CA-P and the key pattern portion KA-P may act as a stopper of the etching process. If (e.g., when) the first opening OP1 and the second opening OP2 are completely (e.g., substantially completely) formed, the second photoresist 220 may be removed.

Next, referring back to FIG. 3, the first material layer 120 stacked on the cell pattern portion CA-P and the key pattern portion KA-P may be removed, thereby completing the production of the deposition mask MA. The first material layer 120 may be removed through a wet process. At this time, a thickness of the first material layer 120 which remains between the second opening OP2 and the key pattern portion KA-P may be smaller than a thickness of the first material layer 120 which remains between the first opening OP1 and the cell pattern portion CA-P. Therefore, the first material layer 120 between the second opening OP2 and the key pattern portion KA-P may be removed first.

Accordingly, in the deposition mask MA according to one or more embodiments, the first material layer 120 in the key area KA may be entirely (e.g., substantially entirely) removed, and the key pattern portion KA-P may be to perform precise alignment without interruption by the first material layer 120. A time for the wet process to remove the first material layer 120 in the key area KA may be shortened, and a phenomenon that the cell pattern portion CA-P is damaged due to an increase in the time for performing the wet process may be suppressed or reduced.

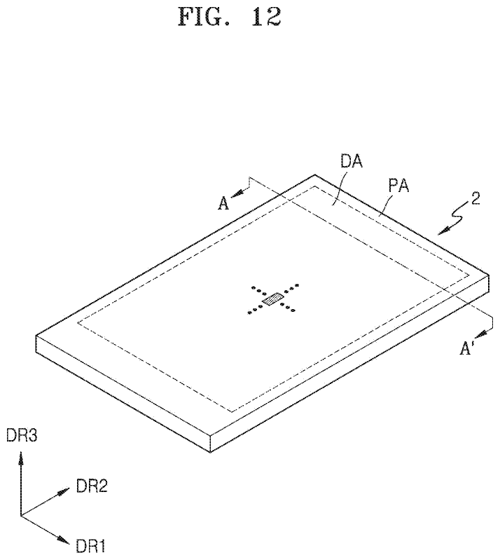

FIG. 12 is a schematic perspective view of a display device according to one or more embodiments.

Referring to FIG. 12, a display device 2 may include a display area DA and a peripheral area PA around (e.g., surrounding) the display area DA. The display area DA may be a portion where images are displayed, and a plurality of pixels PX may be arranged in the display area DA. The display area DA may have one or more suitable shapes, such as a circle (e.g., substantially a circle), an oval (e.g., substantially an oval), a polygon (e.g., substantially a polygon), or a shape of a certain figure.

Each pixel PX of the display device 2 may be an area where light of a certain (e.g., set or predetermined) color is emitted, and the display device 2 may be to provide an image utilizing the light emitted from each of the pixels PX. Each pixel PX may be to emit, for example, red light, green light, blue light, or white light. Each of the pixels PX may denote a sub-pixel and may include a display element and a pixel circuit connected to the display element. The display element may include an organic light-emitting diode or a quantum dot organic light-emitting diode.

The plurality of pixels PX may be arranged in a matrix form along a first direction DR1 and a second direction DR2. The first direction DR1 and the second direction DR2 may be defined as directions which cross each other.

The peripheral area PA may be fully around (e.g., surround) the display area DA. The peripheral area PA may be a kind (type) of non-display area where pixels are not arranged, and drivers or wires to apply electrical signals or power to the pixels PX may be arranged in the peripheral area PA.

The display device 2 may have a rectangular shape (e.g., a substantially rectangular shape) with a horizontal length greater than a vertical length as illustrated in FIG. 12, but embodiments of the present disclosure are not limited thereto. The display device 2 may have one or more suitable shapes, such as a polygon (e.g., substantially a polygon), a circle (e.g., substantially a circle), or an oval (e.g., substantially an oval).

Hereinafter, an organic light-emitting display device will be described in more detail as an example of the display device 2 according to one or more embodiments, but the display device is not limited thereto. In one or more embodiments, other types (kinds) of display devices, such as a quantum dot light-emitting display, may be utilized.

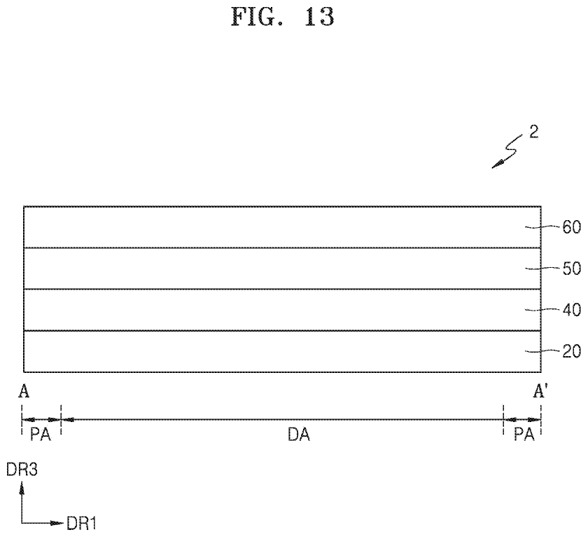

FIG. 13 is a schematic cross-sectional view of a display device according to one or more embodiments. FIG. 13 may correspond to the line A-A′ of FIG. 12.

Referring to FIG. 13, the display device 2 may include a display panel 20, an input sensing layer 40 on the display panel 20, and an optical function layer 50, and the components may all be covered with a window 60. The display device 2 may be one or more suitable types (kinds) of electronic devices, such as mobile phones, laptop computers, and smart watches.

The display panel 20 may be to display an image. The display panel 20 may include the pixels in the display area DA. The pixels may each include a display element and a pixel circuit connected to the display element. The display element may include an organic light-emitting diode or a quantum dot organic light-emitting diode.

The input sensing layer 40 may be to obtain coordinate information according to an external input, for example, a touch event. The input sensing layer 40 may include sensing electrodes (or touch electrodes) and trace lines connected to the sensing electrodes. The input sensing layer 40 may be arranged on the display panel 20. The input sensing layer 40 may be to sense an external input by a mutual-capacitance method or/and a self-capacitance method.

The input sensing layer 40 may be directly on the display panel 20 or may be formed separately and then bonded by an adhesive layer, such as an optical clear (e.g., substantially clear) adhesive. For example, the input sensing layer 40 may be formed continuously after a process of forming the display panel 20. In this case, the input sensing layer 40 may be understood as a portion of the display panel 20, and an adhesive layer may not be arranged between the input sensing layer 40 and the display panel 20. Although FIG. 13 illustrates that the input sensing layer 40 is arranged between the display panel 20 and the optical function layer 50, the input sensing layer 40, in one or more embodiments, may be arranged above the optical function layer 50.

The optical function layer 50 may include an anti-reflection layer. The anti-reflection layer may be to reduce the reflectance of light (external light) which is incident from the outside toward the display panel 20 through the window 60. In one or more embodiments, the anti-reflection layer may include a black matrix and color filters. The color filters may be arranged in consideration of the color of light emitted from each pixel of the display panel 20.

In one or more embodiments, the anti-reflection layer may include a phase retarder and a polarizer. The phase retarder may be of a film type (kind) or a liquid crystal coating type (kind). The polarizer may also be of a film type (kind) or a liquid crystal coating type (kind). The film type (kind) may include a stretched synthetic resin film, and the liquid crystal coating type (kind) may include liquid crystals in a certain (e.g., set or predetermined) arrangement. The phase retarder and the polarizer may further include a protective film. The phase retarder and polarizer or the protective film may be defined as a base layer of the anti-reflection layer.

In one or more embodiments, the anti-reflection layer may include a destructive interference structure. The destructive interference structure may include a first reflective layer and a second reflective layer on different layers. First reflected light and second reflected light, which are respectively reflected from the first reflective layer and the second reflective layer, may be to destructively interfere with each other, and thus, the reflectance of external light may be reduced.

In one or more embodiments, the optical function layer 50 may be formed continuously after a process of forming the display panel 20 and/or the input sensing layer 40. In this case, an adhesive layer may not be arranged between the optical function layer 50, the display panel 20, and/or the input sensing layer 40.

In one or more embodiments, a layer which includes an optically transparent (e.g., substantially transparent) adhesive or an optically transparent (e.g., substantially transparent) resin may be included between the window 60 and the optical function layer 50.

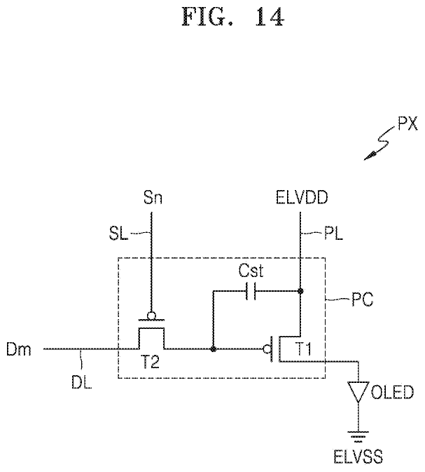

FIG. 14 is a view of an equivalent circuit of a pixel in a display device according to one or more embodiments.

Referring to FIG. 14, a pixel PX may include a pixel circuit PC and an organic light-emitting diode OLED as a display element connected to the pixel circuit PC. The pixel circuit PC may include a first thin-film transistor T1, a second thin-film transistor T2, and a storage capacitor Cst. Each pixel PX may be to emit, for example, red light, green light, or blue light or red light, green light, blue light, or white light through the organic light-emitting diode OLED.

The second thin-film transistor T2 may be a switching thin-film transistor, which may be connected to a scan line SL and a data line DL, and may be to transmit a data signal Dm input from the data line DL to the first thin-film transistor T1 based on a switching signal Sn input from the scan line SL. The storage capacitor Cst may be connected to the second thin-film transistor T2 and a driving voltage line PL and may be to store a voltage corresponding to a difference between a voltage transmitted from the second thin-film transistor T2 and a driving voltage ELVDD applied to the driving voltage line PL.

The first thin-film transistor T1 may be a driving thin-film transistor, which may be connected to the driving voltage line PL and the storage capacitor Cst, and may be to control a driving current, which flows in the organic light-emitting diode OLED from the driving voltage line PL, according to a voltage value stored in the storage capacitor Cst. The organic light-emitting diode OLED may be to emit light with a certain (e.g., set or predetermined) brightness according to the driving current. A counter electrode (e.g., a cathode) of the organic light-emitting diode OLED may be to receive a common voltage ELVSS.

FIG. 14 illustrates a case where the pixel circuit PC includes two thin-film transistors and one storage capacitor, but embodiments of the present disclosure are not limited thereto. The number of thin-film transistors and the number of storage capacitors may vary depending on the design of the pixel circuit PC. For example, the pixel circuit PC may include four, five, or more thin-film transistors in addition to the two thin-film transistors as described in one or more embodiments.

FIG. 15 is a schematic cross-sectional view of a display panel 20 according to one or more embodiments.

Referring to FIG. 15, the display panel 20 may include a substrate 301, a thin-film transistor TR on the substrate 301, and a display element LD on the thin-film transistor TR. The thin-film transistor TR and the display element LD as illustrated in FIG. 15 may correspond to the first thin-film transistor T1 and the organic light-emitting diode OLED as illustrated in FIG. 14, respectively. The display panel 20 may include an organic light-emitting diode as the display element LD, but embodiments of the present disclosure are not limited thereto.

The substrate 301 may include a glass material and/or a polymer resin. In one or more embodiments, the substrate 301 may have a multilayer structure in which a first layer including a polymer resin and a second layer suppressing penetration (or reducing a degree or occurrence of penetration) of external foreign substances are cross-stacked.

The first layer may include a polymer resin, for example, polyethersulfone (PES), polyarylate (PAR), polyetherimide (PEI), polyethylene naphthalate (PEN), polyethylene terephthalate (PET), polyphenylene sulfide (PPS), polyimide (PI), polycarbonate (PC), cellulose triacetate (TAC), and/or cellulose acetate propionate (CAP).

The second layer may include an inorganic material, for example, silicon nitride (e.g., SiₓN_{y}, wherein 0<x≤3 and 0<y≤4; e.g., Si₃N₄) and/or silicon oxide (e.g., SiOₓ, wherein 0<x≤2; e.g., SiO₂).

A buffer layer 302 may be on the substrate 301 to suppress impurities from penetrating (or to reduce a degree to or occurrence of which impurities penetrate) into a semiconductor layer AP of the thin-film transistor TR. The buffer layer 302 may include an inorganic insulating (e.g., electrically insulating) material, for example, silicon nitride (e.g., SiₓN_{y}, wherein 0<x≤3 and 0<y≤4; e.g., Si₃N₄), silicon oxynitride (e.g., SiₓON_{y}, wherein 0<x≤2 and 0<y≤2; e.g., SiON or Si₂N₂O), and silicon oxide (e.g., SiOₓ, wherein 0<x≤2; e.g., SiO₂), and may have a single-layer structure or a multilayer structure including the inorganic insulating material.

The thin-film transistor TR may be arranged on the buffer layer 302. The thin-film transistor TR may include a semiconductor layer AP, a gate electrode GE, a source electrode SE, and a drain electrode DE.

The semiconductor layer AP may include a source region S, a drain region D, and a channel region C between the source region S and the drain region D. The semiconductor layer AP may include polysilicon. In one or more embodiments, the semiconductor layer AP may include amorphous (e.g., non-crystalline) silicon, an oxide semiconductor, and/or an organic semiconductor. The gate electrode GE may include a low-resistance (e.g., low electrical resistance) metal material. The gate electrode GE may include a conductive (e.g., electrically conductive) material including molybdenum (Mo), aluminum (Al), copper (Cu), titanium (Ti), and/or the like, and may have a multilayer structure or a single-layer structure including the material.

A gate insulating layer 303 which is between the semiconductor layer AP and the gate electrode GE may include an inorganic insulating (e.g., electrically insulating) material, for example, silicon oxide (e.g., SiOₓ, wherein 0<x≤2; e.g., SiO₂), silicon nitride (e.g., SiₓN_{y}, wherein 0<x≤3 and 0<y≤4; e.g., Si₃N₄), silicon oxynitride (e.g., SiₓON_{y}, wherein 0<x≤2 and 0<y≤2; e.g., SiON or Si₂N₂O), aluminum oxide (e.g., AlOₓ, wherein 0<x≤2; e.g., Al₂O₃), titanium oxide (e.g., TiOₓ, wherein 0<x≤2; e.g., TiO₂), tantalum oxide (e.g., TaOₓ, wherein 0<x≤3; e.g., Ta₂O₅), and hafnium oxide (e.g., HfOₓ, wherein 0<x≤2; e.g., HfO₂). The gate insulating layer 303 may have a single-layer structure or a multilayer structure including the material.

An interlayer insulating layer 305 may be on the gate electrode GE. The interlayer insulating layer 305 may include an inorganic insulating (e.g., electrically insulating) material, for example, silicon oxide (e.g., SiOₓ, wherein 0<x≤2; e.g., SiO₂), silicon nitride (e.g., SiₓN_{y}, wherein 0<x≤3 and 0<y≤4; e.g., Si₃N₄), silicon oxynitride (e.g., SiₓON_{y}, wherein 0<x≤2 and 0<y≤2; e.g., SiON or Si₂N₂O), aluminum oxide (e.g., AlOₓ, wherein 0<x≤2; e.g., Al₂O₃), titanium oxide (e.g., TiOₓ, wherein 0<x≤2; e.g., TiO₂), tantalum oxide (e.g., TaOₓ, wherein 0<x≤3; e.g., Ta₂O₅), and hafnium oxide (e.g., HfOₓ, wherein 0<x≤2; e.g., HfO₂). The interlayer insulating layer 305 may have a single-layer structure or a multilayer structure including the material.

The source electrode SE and the drain electrode DE may be on the interlayer insulating layer 305. The source electrode SE and the drain electrode DE may include a material with good or suitable conductivity (e.g., electrical conductivity). The source electrode SE and the drain electrode DE may include a conductive (e.g., electrically conductive) material including molybdenum (Mo), aluminum (Al), copper (Cu), titanium (Ti), and/or the like, and may have a multilayer structure or a single-layer structure including the material. In one or more embodiments, the source electrode SE and the drain electrode DE may have a multilayer structure of Ti/Al/Ti.

A planarization layer 307 may be on the source electrode SE and the drain electrode DE. The planarization layer 307 may include an organic insulating (e.g., electrically insulating) layer, for example, a general-purpose polymer, such as polymethylmethacrylate (PMMA) and/or polystyrene (PS), a polymer derivative having a phenol group, an acrylic polymer, an imide polymer, an aryl ether polymer, an amide-based polymer, a fluorinated polymer, a p-xylene polymer, a vinyl alcohol polymer, and a (e.g., any suitable) blend thereof. In one or more embodiments, the planarization layer 307 may include polyimide. The planarization layer 307 may be to eliminate a step caused by the thin-film transistor TR. A surface of the planarization layer 307 opposing the display element LD may be a flat (e.g., substantially flat) surface.

The display element LD which is electrically connected to the thin-film transistor TR may be on the planarization layer 307. The display element LD may include a pixel electrode E1, an intermediate layer EL, and a counter electrode E2 which are sequentially stacked on the planarization layer 307.

The pixel electrode E1 may be on the planarization layer 307. The pixel electrode E1 may be electrically connected to the drain electrode DE of the thin-film transistor TR through a contact hole which is formed through the planarization layer 307. The pixel electrode E1 may include a conductive (e.g., electrically conductive) oxide, for example, indium tin oxide (ITO), indium zinc oxide (IZO), zinc oxide (e.g., ZnOₓ, wherein 0<x≤2; e.g., ZnO or ZnO₂), indium oxide (e.g., InOₓ, wherein 0<x≤2; e.g., In₂O₃), indium gallium oxide (IGO), and/or aluminum zinc oxide (AZO). In one or more embodiments, the pixel electrode E1 may include a reflective film including silver (Ag), magnesium (Mg), aluminum (Al), platinum (Pt), palladium (Pd), gold (Au), nickel (Ni), neodymium (Nd), iridium (Ir), chromium (Cr), or compounds thereof. In one or more embodiments, the pixel electrode E1 may further include a film which includes ITO, IZO, ZnO, and/or In₂O₃ and is located above/below the reflective film.

A pixel defining layer 309 may be on the pixel electrode E1. The pixel defining layer 309 may have an opening corresponding to a pixel, for example, an opening through which at least a central portion of the pixel electrode E1 is exposed, thereby defining an emission area. The pixel defining layer 309 may overlap an edge of the pixel electrode E1 in case of being viewed from a direction (a DR3 direction) normal (e.g., substantially perpendicular) to the substrate 301. The pixel defining layer 309 may include an inorganic insulating (e.g., electrically insulating) material, for example, silicon nitride (e.g., SiₓN_{y}, wherein 0<x≤3 and 0<y≤4; e.g., Si₃N₄), silicon oxynitride (e.g., SiₓON_{y}, wherein 0<x≤2 and 0<y≤2; e.g., SiON or Si₂N₂O), and/or silicon oxide (e.g., SiOₓ, wherein 0<x≤2; e.g., SiO₂). The pixel electrode E1 may be to serve as an anode electrode.

The intermediate layer EL may include a low-molecular-weight material and/or a high-molecular-weight material. If (e.g., when) the intermediate layer EL includes a low-molecular-weight material, the intermediate layer EL may have a single-layer structure or a multilayer stacked structure including a hole injection layer, a hole transport layer, an emission layer, an electron transport layer, and an electron injection layer, and may include one or more suitable organic materials including copper phthalocyanine (CuPc), N,N′-di(naphthalene-1-yl)-N,N′-diphenyl-benzidine (NPB), and/or tris-8-hydroxyquinoline aluminum (Alq3). These layers may be formed by vacuum deposition.

If (e.g., when) the intermediate layer EL includes a high-molecular-weight material, the intermediate layer EL may have a structure including a hole transport layer HTL and an emission layer EML. In this instance, the hole transport layer may include poly(3,4-ethylenedioxythiophene) (PEDOT), and the emission layer may include a high-molecular-weight material, such as poly-phenylenevinylene (PPV) and/or polyfluorene. The structure of the intermediate layer EL is not limited to that described herein and may have one or more suitable structures. For example, at least one selected from among the layers forming the intermediate layer EL may be formed integrally over a plurality of pixel electrodes E1. In one or more embodiments, the intermediate layer EL may include a layer patterned to correspond to each of the plurality of pixel electrodes E1.

The counter electrode E2 may be to serve as a cathode electrode. The counter electrode E2 may be a transparent (e.g., substantially transparent) electrode or a reflective electrode. In one or more embodiments, the counter electrode E2 may be a transparent electrode or a semitransparent electrode and may be a thin film of a metal having a low work function, including Li, Ca, LiF/Ca, LiF/Al, Al, Ag, Mg, and compounds thereof. The counter electrode E2 may be arranged over the plurality of pixels and may be a common electrode of the display panel 20.

The pixel electrode E1, the intermediate layer EL, and the counter electrode E2 may form the display element LD. The display element LD may be to emit light based on a driving current transmitted from the thin-film transistor TR.

The display device 2 according to one or more embodiments may be applied to one or more suitable electronic devices. An electronic device according to one or more embodiments may include the display device 2 as described in one or more embodiments, and may further include a module or device having additional functions in addition to the display device 2.

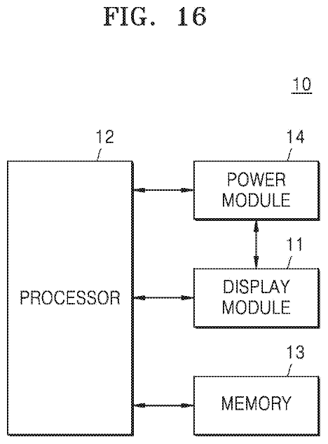

FIG. 16 is a block diagram of an electronic device 10 according to one or more embodiments.

Referring to FIG. 16, an electronic device 10 according to one or more embodiments may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 13 may be to store data information which is desired or required for the operation of the processor 12 or the display module 11. If (e.g., when) the processor 12 executes an application stored in the memory 13, an image data signal and/or an input control signal may be transmitted to the display module 11, and the display module 11 may be to process the received signal and output image information through a display screen.

The power module 14 may include a power supply module, such as a power adapter or a battery device, and a power conversion module which converts power supplied by the power supply module to generate power desired or required for the operation of the electronic device 10.

At least one selected from among the components of the electronic device 10 may be in the display device according to one or more embodiments. One or more of individual modules functionally in a single module may be in the display device and others may be provided separately from the display device. For example, the display device may include the display module 11, and the processor 12, the memory 13, and the power module 14 may be provided as other devices inside the electronic device 10 other than the display device.

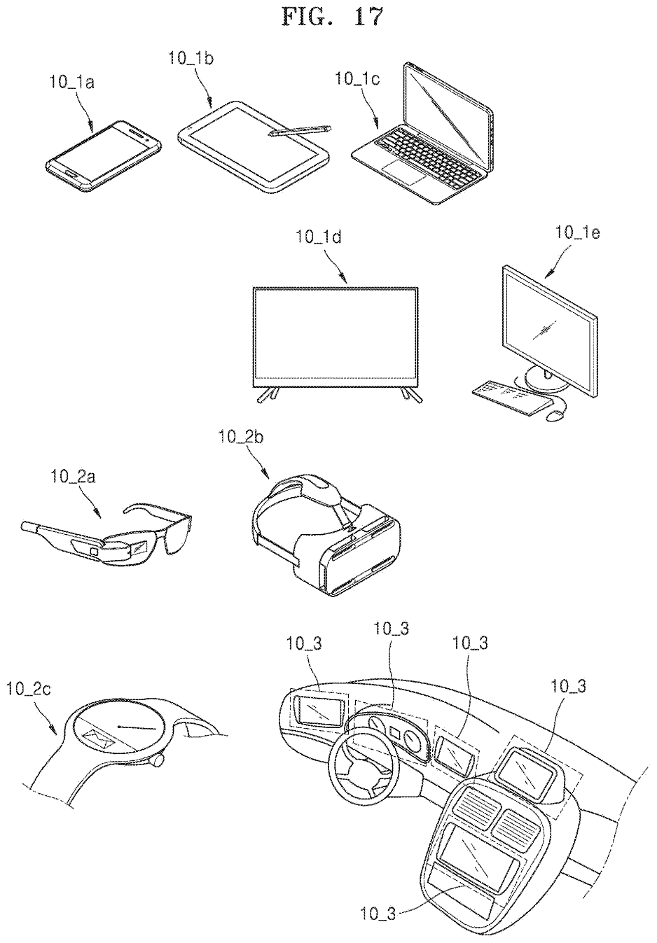

FIG. 17 is schematic views of electronic devices according to one or more embodiments.

Referring to FIG. 17, one or more suitable electronic devices to which the display device according to one or more embodiments is applied may include image display electronic devices, such as a smart phone 10_1a, a tablet PC 10_1b, a laptop 10_1c, a TV 10_1d, and a desk monitor 10_1e, wearable electronic devices including display modules, such as smart glasses 10_2a, a head mounted display 10_2b, and a smart watch 10_2c, and vehicle electronic devices 10_3 including display modules, such as a dashboard of an automobile, center fascia, a center information display (CID) arranged on the dashboard, and a room mirror display.

According to one or more embodiments, a recognition rate of a key pattern for alignment with a substrate on which a deposition mask is to be deposited may be improved or enhanced, and the alignment of the deposition mask may be performed more precisely.

According to one or more embodiments, durability and manufacturing efficiency of the deposition mask may be improved or enhanced.

According to one or more embodiments, the enhanced recognition rate of the key pattern not only facilitates more accurate alignment between the deposition mask and the substrate, but also contributes to reducing alignment errors during high-resolution deposition processes. This precision reduces material waste and improves or enhances layer uniformity, which is desired for advanced electronic devices. Furthermore, the improved or enhanced durability of the deposition mask-achieved through designed material selection and structural design-extends its usable life across two or more fabrication cycles. Combined with streamlined manufacturing, such as efficient or suitable groove formation and selective material removal, these advancements lead to greater throughput and cost-effectiveness in production environments, supporting scalable fabrication of next generation display technologies.

A light-emitting device, a display device, a display apparatus, an electronic device, an electronic apparatus, a device for manufacturing substantially the same and/or any other relevant devices or components according to one or more embodiments of the present disclosure may be implemented by utilizing any suitable hardware, firmware (e.g., an application-specific integrated circuit), software, or a (e.g., any suitable) combination of software, firmware, and hardware. For example, the one or more components of the device may be provided on one integrated circuit (IC) chip or on separate IC chips. Further, the one or more components of the device may be implemented on a flexible printed circuit film, a tape carrier package (TCP), and/or a printed circuit board (PCB), or provided on one substrate. Further, the one or more components of the device may be a process or thread, running on one or more processors, in one or more computing devices, executing computer program instructions and interacting with other system components for performing the one or more functionalities described herein. The computer program instructions may be stored in a memory which may be implemented in a computing device utilizing a standard memory device, such as, for example, a random access memory (RAM). The computer program instructions may also be stored in other non-transitory computer readable media, such as, for example, a CD-ROM, flash drive, and/or the like. Also, a person of skill in the art should recognize that the functionality of one or more computing devices may be combined or integrated into a single computing device, or the functionality of a particular computing device may be distributed across one or more other computing devices without departing from the scope of the present disclosure.

While the subject matter of the present disclosure has been described in connection with certain embodiments, it is to be understood that the subject matter of the present disclosure is not limited to the disclosed embodiments, but, on the contrary, the present disclosure is intended to cover one or more suitable modifications and equivalent arrangements included within the spirit and scope of the appended claims, and equivalents thereof.

What is claimed is:

1. A deposition mask comprising:
a base layer having a first opening and a second opening, the first and second openings having different widths; and
a mask pattern layer on the base layer, the mask pattern layer comprising:
a cell pattern portion overlapping the first opening; and
a key pattern portion overlapping the second opening,
wherein a first virtual line, which is substantially parallel to the base layer and passes through a center of the cell pattern portion, is substantially parallel to a second virtual line, which is substantially parallel to the base layer and passes through a center of the key pattern portion.

2. The deposition mask as claimed in claim 1, wherein the second virtual line is closer to the base layer than the first virtual line is to the base layer.

3. The deposition mask as claimed in claim 1, wherein the mask pattern layer comprises silicon nitride.

4. The deposition mask as claimed in claim 1, wherein a thickness of the mask pattern layer is in a range of 0.5 μm to 2 μm.

5. The deposition mask as claimed in claim 1, wherein the key pattern portion is spaced farther from a center of the mask pattern layer than the cell pattern portion is spaced from the center of the mask pattern layer.

6. The deposition mask as claimed in claim 1, wherein the first opening and the second opening are each arranged such that a width on one side is smaller than a width on another side.

7. A method comprising:
forming a first material layer on a base layer;
forming at least one groove in a surface of the first material layer;
forming a mask pattern layer on the first material layer;
patterning a surface of the mask pattern layer to form a key pattern portion overlapping the at least one groove and a cell pattern portion spaced from the key pattern portion;
forming, in the base layer, a first opening overlapping the cell pattern portion and a second opening overlapping the key pattern portion; and
removing the first material layer between the cell pattern portion and the first opening and between the key pattern portion and the second opening,
wherein the method is a method of manufacturing a deposition mask.

8. The method as claimed in claim 7, wherein a width of the at least one groove is greater than a width of the key pattern portion.

9. The method as claimed in claim 8, wherein the width of the at least one groove is equal to or less than twice the width of the key pattern portion.

10. The method as claimed in claim 7, wherein a thickness of the at least one groove has a value in a range of 30% to 80% of a thickness of the first material layer.

11. The method as claimed in claim 7, wherein a first virtual line which is substantially parallel to the base layer and passes through a center of the cell pattern portion is substantially parallel to a second virtual line which is substantially parallel to the base layer and passes through a center of the key pattern portion.

12. The method as claimed in claim 11, wherein the second virtual line is closer to the base layer than the first virtual line is to the base layer.

13. The method as claimed in claim 7, wherein the mask pattern layer comprises silicon nitride.

14. The method as claimed in claim 7, wherein a thickness of the mask pattern layer is in a range of 0.5 μm to 2 μm.

15. The method as claimed in claim 7, wherein the key pattern portion is spaced farther from a center of the mask pattern layer than the cell pattern portion is spaced from the center of the mask pattern layer.

16. The method as claimed in claim 7, wherein the first opening and the second opening are each formed such that an upper width is smaller than a lower width.

17. The method as claimed in claim 7, wherein the first material layer comprises silicon oxide.

18. The method as claimed in claim 7, wherein a thickness of the cell pattern portion is substantially equal to a thickness of the key pattern portion.

19. The method as claimed in claim 7, wherein a width of the key pattern portion is smaller than a width of the cell pattern portion.

20. An electronic device comprising:
a substrate;
a plurality of thin-film transistors on the substrate;
a plurality of pixel electrodes electrically connected to the plurality of thin-film transistors;
a plurality of intermediate layers on the plurality of pixel electrodes; and
a counter electrode on the plurality of intermediate layers,
wherein at least one of the plurality of thin-film transistors, the plurality of pixel electrodes, the plurality of intermediate layers, the counter electrode, or a combination thereof is formed utilizing the deposition mask as claimed in claim 1.
